(19) United States
(12) Patent Application Publication
(10) Pub. No.: US 2010/0072943 A1
(43) Pub. Date: Mar. 25, 2010

(54) VEHICLE ENERGY RECOVERY SYSTEM

(75) Inventor: Imad Mahawili, Grand Haven, MI (US)

Correspondence Address: VAN DYKE, GARDNER, LINN & BURKHART, LLP, SUITE 207, 2851 CHARLEVOIX DRIVE, S.E., GRAND RAPIDS, MI, 49546, US

(73) Assignee: ENERGY RECOVERY TECHNOLOGY, LLC, Grand Haven, MI (US)

(21) Appl. No.: 12/567,082

(22) Filed: Sep. 25, 2009

Related U.S. Application Data
(60) Provisional application No. 61/099,972, filed on Sep. 25, 2008.

(51) Int. Cl. H01M 10/46; H01L 35/00; B62D 63/00; B60L 1/00

(52) U.S. Cl. 320/101; 136/205; 136/201; 180/313; 307/9.1

(57) ABSTRACT

A system and method for recovering heat energy from a vehicle, such as a car, truck, railroad, or airplane, is disclosed. The system and method include mounting a thermoelectric unit to the vehicle at one or more locations where a temperature gradient is expected. Due to the Seebeck effect, the thermoelectric unit generates a voltage and current, which may then be temporarily stored on the vehicle and/or transferred inductively to an off-vehicle location.

### CROSS-REFERENCE TO RELATED APPLICATIONS

This application claims priority to U.S. provisional application Ser. No. 61/099,972, filed Sep. 25, 2008 by Imad Mahawili, Ph.D., and entitled VEHICLE ENERGY RECOVERY SYSTEM, the complete disclosure of which is hereby incorporated herein by reference.

### BACKGROUND OF THE INVENTION

The present invention relates to a system for recovering energy from vehicles that would otherwise be wasted, and more particularly to a system adapted to be used with cars, trucks, trains, or other vehicles utilizing an internal combustion engine.

### SUMMARY OF THE INVENTION

According to one aspect, the present invention provides a system and method for recovering at least a portion of the heat energy that would normally be lost from a structure that generates heat as a by product of the structure's main function. Such structures may include internal combustion engines, vehicle brakes, or other types of structures. The system and method may be applied to conventional cars, trucks, train engines, or other vehicles having internal combustion engines, as well as to other devices. The energy is recovered through the use of one or more thermoelectric units positioned on the structure at one or more locations having relatively high temperature gradients. The recovered energy is transferred to one or more physically separated energy collectors that store, transfer, or use the collected energy. The collected energy is thereby not wasted. The recovered energy may be used for any of a variety of different suitable purposes.

According to another aspect of the invention, a vehicle is provided that includes a thermoelectric unit and an energy transfer device. The thermoelectric unit is adapted to generate electrical energy based upon differences in temperature, and is placed in a location on the vehicle having a temperature that is elevated relative to ambient air. The energy transfer device is adapted to inductively transfer at least some of the electrical energy off of the vehicle to an energy collector.

According to another aspect of the invention, an energy recovery system is provided that includes a plurality of energy collectors positioned on or in a plurality of surfaces over which one or more vehicles are intended to move. The system further includes at least one vehicle adapted to move over at least one of said plurality of surfaces wherein the vehicle includes an internal combustion engine, a thermoelectric unit, and an energy transfer system. The thermoelectric unit generates electrical energy based upon differences in temperature, and is placed in a location on the vehicle having a temperature that is elevated relative to ambient air. The energy transfer device inductively transfers at least some of the electrical energy off of the vehicle to one or more of the energy collectors.

According to other aspects of the invention, the vehicle may be an automobile or truck and the energy collectors may be positioned in or on one or more roadways such that the vehicle may transfer electrical energy to the collectors while the vehicle is either parked, idling, or driving on the roadway. The thermoelectric unit may be positioned within, or adjacent to, a portion of the exhaust system of the internal combustion engine. The vehicle may further include one or more batteries in which the vehicle may temporarily store the electrical energy from the thermoelectric unit until the vehicle is moved to within a vicinity of the energy collector in which energy transfer may usefully occur. The thermoelectric unit may be made from thermoelectric materials that have high operating temperatures, such as at least 500 degrees Kelvin or higher. Such materials may include cobalt antimony compounds, as well as Zintl systems, such as, but not limited to, yttrium manganese antimony compounds. The vehicle may further include a sensor adapted to detect the presence of the energy collector such that the energy transfer device is only activated when it is within the presence of the energy collector.

### BRIEF DESCRIPTION OF THE DRAWINGS

FIG. 1 is a schematic diagram of a vehicular energy recovery system according to one aspect of the present invention.

### DETAILED DESCRIPTION OF THE EMBODIMENTS

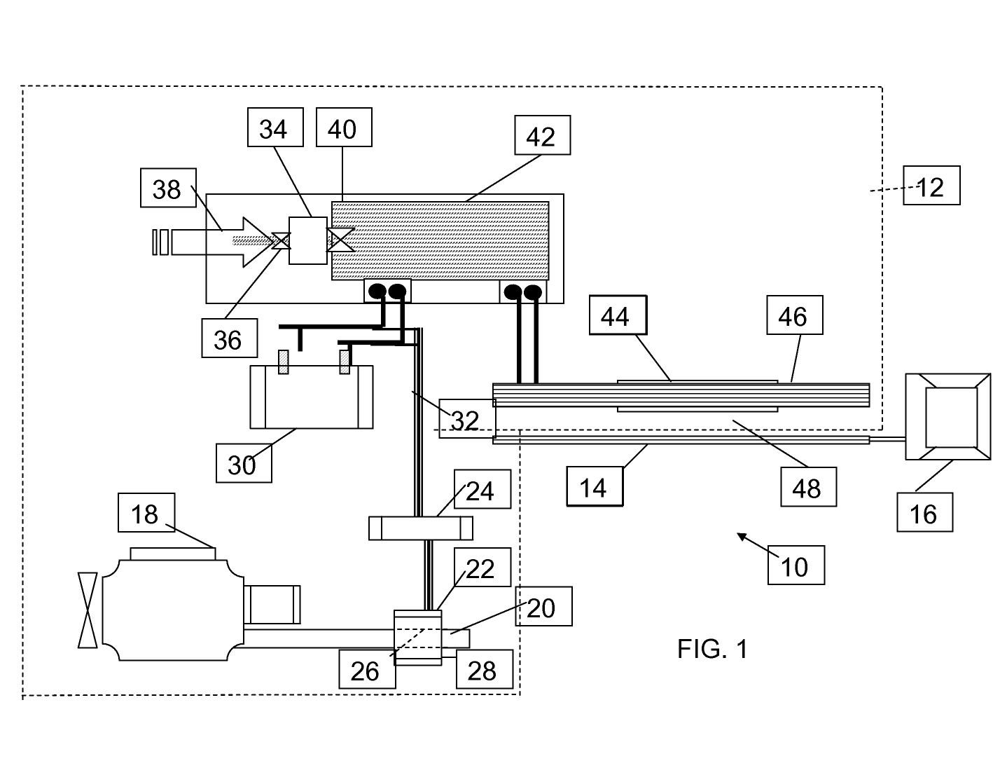

An energy recovery system 10 according to one aspect of the present invention is depicted in FIG. 1. Energy recovery system 10 includes a vehicle 12, an off-vehicle energy collector 14, and an energy storage device 16. Vehicle 12 may take on a wide variety of forms, and may be an automobile, a truck, a train engine, or any other type of vehicle that includes a source of heat from which electrical energy may be generated, as will be discussed in greater detail below. In the embodiment depicted in FIG. 1, vehicle 12 includes an internal combustion engine 18 that supplies power to one or more wheels (not shown) on the vehicle in order for the vehicle to move. Engine 18 includes an exhaust system 20 that exhausts the hot gases emitted from the combustion of the vehicle's fuel in engine 18.

A thermoelectric unit 22 is positioned along, inside of, or partially inside of, exhaust system 20 such that a hot region 26 of thermoelectric unit 22 is exposed to the relatively high temperatures of the exhaust gas, and a cool region 28 is exposed to the relatively lower temperatures of the ambient surrounding air. In the embodiment shown in FIG. 1, hot region 26 refers to the interior of unit 22 while cool region 28 refers to the exterior of unit 22. Other arrangements of hot and cool regions 26 and 28 may be implemented. Thermoelectric unit 22 is manufactured from a thermoelectric material that generates an electrical voltage in the presence of a temperature gradient across the thermoelectric material. Such materials behave in accordance with the Seebeck effect, which is the reverse of the Peltier effect. When internal combustion engine 18 is operating, or was recently operated, a temperature gradient will exist across the first and second regions 26 and 28 of thermoelectric unit 22. Thermoelectric unit 22 utilizes this temperature difference to generate a voltage.

Thermoelectric unit 22 may be manufactured from a wide variety of known thermoelectric materials. For example, thermoelectric unit 22 may be completely made out of, or may contain portions of, conventional and commercially available silicon-based thermoelectric materials. Such materials are available from multiple vendors including, but not limited to, Melcor (a unit of Laird Technologies) which has a place of business at 1040 Spruce St., Trenton, N.J., 08648, as well as Marlow Industries, a subsidiary of II-VI Incorporated, having a place of business at 10451 Vista Park Road, Dallas, Tex., 75238. Such silicon-based thermoelectric materials, however, may not be able to withstand the high temperatures of the particular structure to which unit 22 is coupled.

For applications involving higher temperatures, thermoelectric unit 22 may be manufactured from non-silicon based thermoelectric materials, either alone or in combination with silicon-based thermoelectric materials. Non-silicon based thermoelectric materials are currently available that are able to withstand the relatively high temperatures of the exhaust gases emitted from internal combustion engine 18. In some embodiments, thermoelectric unit 22 may be manufactured from thermoelectric materials that are able to withstand temperatures at least as high as 500 degrees Kelvin, and which may be able to withstand temperatures as high as 900 degrees Kelvin, or even greater. Such high temperature thermoelectric materials may include known high temperature thermoelectric materials (such as, but not limited to, cobalt antimony compounds and Zintl phase systems, such as, but not limited to, yttrium manganese antimony compounds), as well as later-developed high temperature thermoelectric materials. Thermoelectric unit 22 therefore may be silicon based, non-silicon based, or a combination thereof. Thermoelectric unit 22 also may comprise one or more types of materials from within these two categories (silicon and non-silicon). Further, whatever the choice of material or materials, thermoelectric unit 22 may comprise multiple pieces of thermoelectric materials cascaded together, or otherwise arranged in whatever manners are suitable for generating electricity from the neighboring heat source.

Thermoelectric unit 22 may be constructed such that its hot region 26 is exposed to the relatively high temperatures of the exhaust gases of internal combustion engine 18, such as being placed inside of the exhaust pipe leading away from the engine, and that its cool region 28 is exposed to the relatively cooler ambient air outside of the exhaust pipe. Thermoelectric unit 22 may alternatively be placed in other areas of the vehicle where a temperature gradient exists, such as, but not limited to, adjacent the engine block, the radiator, or one or more brakes of the vehicle. Other arrangement are also possible. Regardless of the position of thermoelectric unit 22, its relatively cooler region 28 may be in thermal communication with a heat exchanger that helps dissipate heat and maintain the cooler region 28 at a lower temperature relative to hot region 26. Such a heat exchanger may involve contact of cooler region 28 with an air or water cooling system (or other liquid cooling system), or a combination thereof. The cooling system may be a cooling system separate from the cooling system used to cool internal combustion engine 18, or it may be the same cooling system, or a combination of a partially shared and partially separate cooling system.

Thermoelectric controller 24 is in electrical communication with one or more thermoelectric units 22. Controller 24 utilizes the electrical voltage generated by thermoelectric unit 22 to convert it to electrical energy that may either be stored in a vehicle battery 30 or other type of vehicle electrical storage unit (e.g. capacitors, flywheel, etc), or that may be transferred directly off of the vehicle 12 via inductive coupling with an energy collector 14 as discussed in greater detail below. In the embodiment illustrated in FIG. 1, controller 24 is coupled by wires 32 to the positive and negative terminals of vehicle battery 30 such that the voltage generated by thermoelectric unit 22 is either used to re-charge battery 30 or is transferred directly to an amplifier 42, as will be discussed more below. Battery 30 may be the battery (or batteries) that is used by the vehicle 12 to supply electrical energy to the electrical systems of the vehicle and which, in the case of an automobile or truck, is coupled to the vehicle's alternator for recharging, or it may be a separate battery specifically devoted to storing electrical energy harnessed from thermoelectric unit 22. The circuitry of controller 24 that carries out the function of harnessing the voltage of thermoelectric unit 22 and transferring it to battery 30 may take on any of a variety of forms, as would be known to one skilled in the art.

Electrical energy generated by thermoelectric unit 22 is transferred off of the vehicle, in the illustrated embodiment, by using the electrical energy to amplify an oscillating signal generated by an oscillator 34. As is described in more detail in commonly-owned U.S. patent application Ser. No. 61/014,175, entitled A METHOD OF ELECTRIC ENERGY TRANSFER BETWEEN A VEHICLE AND A STATIONARY COLLECTOR, and filed on Dec. 17, 2007 by Imad Mahawili, the complete disclosure of which is hereby incorporated herein by reference, oscillator 34 may be coupled to a switch 36 that activates oscillator 34 when vehicle 12 is within a range of energy collector 14 that is close enough for inductive energy transfer to occur. Switch 36 may be activated by a signal 38 from a sensor (not shown) that detects that vehicle 12 is within such range of energy collector 14. When switch 36 is switched on, it activates oscillator 34, which begins to generate an oscillating signal. The oscillating signal may pass through a preamplifier 40 prior to being fed into amplifier 42. Amplifier 42 uses electrical energy to amplify the oscillating signal. The electrical energy may come from battery 30, or it may come directly from thermoelectric unit 22 via wires 32, or it may come from a combination of both of these sources.

After being amplified in amplifier 42, the oscillating signal is fed to a magnetic field generating coil 44, which may include a core 46 for concentrating the magnetic field generated by coil 44. Coil 44 is positioned on vehicle 12 at a location in which only a relatively small air gap 48 between vehicle 12 and energy collector 14 exists. If vehicle 12 is a car or a truck, coil 44 may be positioned on the underside of the car or truck and energy collector 14 may be positioned on or within the surface of a road. If vehicle 12 is a train engine, coil 44 may also be positioned on the underside of the train engine and energy collector 14 may be positioned on or in between the rail tracks. In other embodiments, coil 44 may be positioned in other locations on the vehicle, such as along a side of the vehicle, or on top of the vehicle, and energy collector 14 may be positioned in a corresponding location such that a relatively small air gap 48, such as several inches, exists between the two at moments when it is desirable to inductively transfer electrical energy off of vehicle 12 to energy collector 14. The amplified oscillating signal that is fed from amplifier 42 to coil 44 causes an oscillating magnetic field to be generated around coil 44 that, when in the proximity of energy collector 14, induces a voltage within energy collector 14. Energy collector 14 utilizes this induced voltage to collect electrical energy from vehicle 12.

In order to facilitate the inductive transfer of electrical energy from vehicle 12 to energy collector 14, vehicle 12 may include an actuator (not shown) for extending and retracting coil 44 toward and away from vehicle 12. Such actuator may take on a variety of different forms, such as, but not limited to, one or more motors, solenoids, hydraulic lines, pressurized air lines, or any other suitable construction for physically extending and retracting coil 44. Further examples of actuators that may be used, as well as the control of the actuator, are discussed in greater detail in U.S. patent application Ser. No. 11/454,948, entitled ENERGY RECOVERY SYSTEM, filed Jun. 16, 2006 by Imad Mahawili, the complete disclosure of which is hereby incorporated herein by reference. Regardless of the physical construction of the actuator, it may be controlled such that coil 44 is extended into closer physical proximity to energy collector 14 at moments when it is desirable to inductively transfer electrical energy from vehicle 12 to energy collector 14, and physically retracted at moments when no inductive transfer of electrical energy is desired. The activation of the actuator may be tied to signal 38, or based upon the same circumstances that lead to the generation of signal 38, or it may be performed independently of signal 38. The retraction and extension of coil 44 helps reduce the air gap 48 between coil 44 and energy collector 14, thereby increasing the efficiency of the inductive energy transfer therebetween.

Energy collectors 14 may take on a wide variety of forms, such as one or more electrically conductive coils, one or more of the circuit sheets disclosed in commonly assigned U.S. patent application Ser. No. 11/828,686, entitled CIRCUIT MODULE, filed on Jul. 26, 2007 by Imad Mahawili, the complete disclosure of which is hereby incorporated by reference herein. Alternatively, energy collectors 14 may comprise conductors, such as the conductors 14 disclosed in U.S. patent application Ser. No. 12/059,433, entitled ENERGY RECOVERY SYSTEM, filed Mar. 31, 2008 by Imad Mahawili, the complete disclosure of which is hereby incorporated herein by reference, as well as any of the other types of energy collectors disclosed therein.

The electrical energy that is transferred off of vehicle 12 to energy collector 14 may be stored in an energy storage device 16. Alternatively, it may be consumed in another application independent from vehicle 12; it may be transferred to another physical location for storage and/or usage; or it may be transferred to the electrical grid that supplies electrical power to homes and businesses. Energy storage device 16 may comprise one or more batteries, fuel cells, capacitors (including electric double layer capacitors and electrochemical double layer capacitors), flywheels, hydroelectric energy storage system, or any combination of these devices with any other known energy storage systems.

Energy collectors 14, when used in an energy recovery system 10 that involves cars and/or trucks, may be physically positioned at various locations on or in roads, driveways, parking spots, or other locations where the vehicle 12 frequently comes to a stop, such as at stop signs, in front of toll booths, etc. Energy collectors 14 may alternatively be positioned in locations where the vehicles are not necessarily expected to stop, but which allow electrical energy to be transferred via inductive coupling between coil 44 and energy collectors 14.

Energy recovery system 10 allows for the recovery and use of energy that would otherwise be wasted by vehicles 12. In particular, energy recovery system 10 allows for the recovery and use of thermal energy that is normally otherwise wasted due to the inefficiencies of internal combustion engines. While some of the electrical energy that is generated by thermoelectric unit 22 may be consumed on-board the vehicle, energy recovery system 10 allows energy beyond the vehicle's on-board electrical needs to be transferred off of the vehicle, where the energy may be used for any suitable purpose. In some embodiments, it may be possible to generate up to 15 kilowatts or more of electrical energy when thermoelectric unit 22 is applied to a conventional automobile. Such amounts of electrical energy have limited, if any, use for the typical on-board electrical energy needs of automobiles and/or trucks, and thus would normally otherwise be wasted in the absence of energy recovery system 10. Energy recovery system 10 thus may transfer valuable electrical energy to the electrical grid, distribute the generation of electrical power, and reduce carbon emissions by displacing fossil fuel used in electric power plants.

While several forms of the invention have been shown and described, other forms will now be apparent to those skilled in the art. For example, alternative embodiments may include multiple thermoelectric units 22 positioned at different locations upon the source of heat, or upon different sources of heat. As another example, thermoelectric units 22 may not be positioned on a vehicle, but instead might be positioned on other objects having a source of heat that can be converted to electricity and transferred to another location. Other examples are also possible. Therefore, it will be understood that the embodiments shown in the drawing and described above are merely for illustrative purposes, and are not intended to limit the scope of the invention, which is defined by the following claims, as interpreted under the principles of patent law including the doctrine of equivalents.

What is claimed is:

1. A vehicle comprising:
a thermoelectric unit adapted to generate electrical energy based upon differences in temperature, said thermoelectric unit being placed in a location on said vehicle having a temperature that is elevated relative to ambient air; and
an energy transfer device adapted to inductively transfer at least some of said electrical energy off of said vehicle to an energy collector.

2. The vehicle of claim 1 further including a battery wherein said vehicle is adapted to store said electrical energy from said thermoelectric unit in said battery if said vehicle is not within a vicinity of said energy collector.

3. The vehicle of claim 1 further including an internal combustion engine adapted to provide energy for driving said vehicle wherein said thermoelectric unit is positioned along an exhaust system of said internal combustion engine.

4. The vehicle of claim 1 wherein said thermoelectric unit includes thermoelectric materials adapted to withstand temperatures at least as high as 500 degrees Kelvin.

5. The vehicle of claim 1 wherein said vehicle is one of an automobile, a truck, and a train.

6. The vehicle of claim 1 wherein said vehicle is one of an automobile and truck, said energy transfer device is positioned on an underside of said one of an automobile and truck, and said energy collector is positioned on or in a surface on which said one of an automobile and truck is intended to drive.

7. The vehicle of claim 1 wherein said energy transfer device includes an oscillator adapted to output an oscillating signal and an amplifier adapted to amplify said oscillating signal and produce an amplified signal; and wherein said energy collector includes a coil adapted to receive said amplified signal, said coil being positioned on or in a surface over which said vehicle is intended to move.

8. The vehicle of claim 1 further including a sensor adapted to detect the presence of said energy collector, said sensor being in communication with said energy transfer device such that said energy transfer device is only activated when said energy transfer device is within the presence of said energy collector.

9. An energy recovery system comprising:
a plurality of energy collectors positioned on or in a plurality of surfaces over which one or more vehicles are intended to move; and
a vehicle adapted to move over said plurality of surfaces, said vehicle including:
(a) an internal combustion engine;
(b) a thermoelectric unit adapted to generate electrical energy based upon differences in temperature, said thermoelectric unit being placed in a location on said vehicle having a temperature that is elevated relative to ambient air; and
(c) an energy transfer device adapted to inductively transfer at least some of said electrical energy off of said vehicle to one or more of said energy collectors.

10. The system of claim 9 wherein said vehicle is a car and said plurality of surfaces include road surfaces.

11. The system of claim 9 wherein said vehicle is a train engine and said plurality of surfaces include surfaces adjacent one or more train tracks.

12. The system of claim 9 wherein said vehicle includes a battery and said vehicle is adapted to store said electrical energy from said thermoelectric unit in said battery if said vehicle is not within a vicinity of one of said energy collectors.

13. The vehicle of claim 9 wherein said thermoelectric unit is positioned along an exhaust system of said internal combustion engine.

14. The vehicle of claim 13 wherein said thermoelectric unit includes thermoelectric materials adapted to withstand temperatures at least as high as 500 degrees Kelvin.

15. A method of recovering energy from a vehicle comprising:
providing a thermoelectric unit adapted to generate electrical energy based upon differences in temperature, said thermoelectric unit being placed in a location on said vehicle having a temperature that is elevated relative to ambient air; and
inductively transferring at least some of said electrical energy off of said vehicle to an energy collector.

16. The method of claim 15 further including positioning said thermoelectric unit along an exhaust system of an internal combustion engine of said vehicle.

17. The method of claim 15 further including positioning said energy collector in or on a surface over which said vehicle is adapted to travel.

18. The method of claim 15 further including providing a battery and storing said electrical energy from said thermoelectric unit in said battery if said vehicle is not within a vicinity of said energy collector.

19. The method of claim 18 further including providing a sensor adapted to detect the presence of said energy collector and inductively transferring said energy off said vehicle to said energy collector only when said vehicle is within the presence of said energy collector.

20. The method of claim 15 further including positioning said thermoelectric unit adjacent to a brake for said vehicle.
